(19) United States
(12) Patent Application Publication
(10) Pub. No.: US 2014/0210279 A1
(43) Pub. Date: Jul. 31, 2014

(54) LAMINATE SURFACE FOR WIRELESS CAPACITIVE POWER

(71) Applicants: Maarten Marinus Johannes Wilhelmus Van Herpen, Heesch (NL); Coen Theodorus Hubertus Fransiscus Liedenbaum, Oss (NL); Oscar Hendrikus Willemsen, Den Bosch (NL)

(72) Inventors: Maarten Marinus Johannes Wilhelmus Van Herpen, Heesch (NL); Coen Theodorus Hubertus Fransiscus Liedenbaum, Oss (NL); Oscar Hendrikus Willemsen, Den Bosch (NL)

(73) Assignee: KONINKLIJKE PHILIPS N.V., EINDHOVEN (NL)

(21) Appl. No.: 14/237,099

(22) PCT Filed: Aug. 2, 2012
(86) PCT No.: PCT/IB2012/053953

§ 371 Date: Feb. 4, 2014

Related U.S. Application Data
(60) Provisional application No. 61/523,967, filed on Aug. 16, 2011.
(60) Provisional application No. 61/670,661, filed on Jul. 12, 2012.

(51) Int. Cl. H04B 5/00; H05K 1/11

(52) U.S. Cl. CPC H04B 5/0012; H05K 1/11
USPC 307/109; 174/255

(57) ABSTRACT

A laminate panel (201) for wireless capacitive power transfer includes a clear protective top layer (206), a photographic layer (205) under the protective top layer (206), a conductive layer (202) under the photographic layer (205), and an inner core layer (203) under the conductive layer (202). One or more conductive layers in the laminate panels form a pair of transmitter electrodes, which couple to a power driver (110).

This application claims the benefit of U.S. provisional application No. 61/523,967 filed on Aug. 16, 2011 and U.S. provisional application No. 61/670,661 filed on Jul. 12, 2012.

The invention generally relates to capacitive powering systems for wireless power transfers and, more particularly, to structures for allowing efficient power transfers from a laminate surface.

A wireless power transfer refers to the supply of electrical power without any wires or contacts, whereby the powering of electronic devices is performed through a wireless medium. Capacitive coupling is one technique used to transfer power wirelessly. This technique is predominantly utilized in data transfer and sensing applications. An example of capacitive coupling is a car-radio antenna that is glued on a window with a pick-up element inside of the car. Capacitive coupling is also utilized for contactless charging of electronic devices.

The subject matter that is regarded as the invention is particularly pointed out and distinctly claimed in the claims at the conclusion of the specification. The foregoing and other features and advantages of the invention are apparent from the following detailed description taken in conjunction with the accompanying drawings.

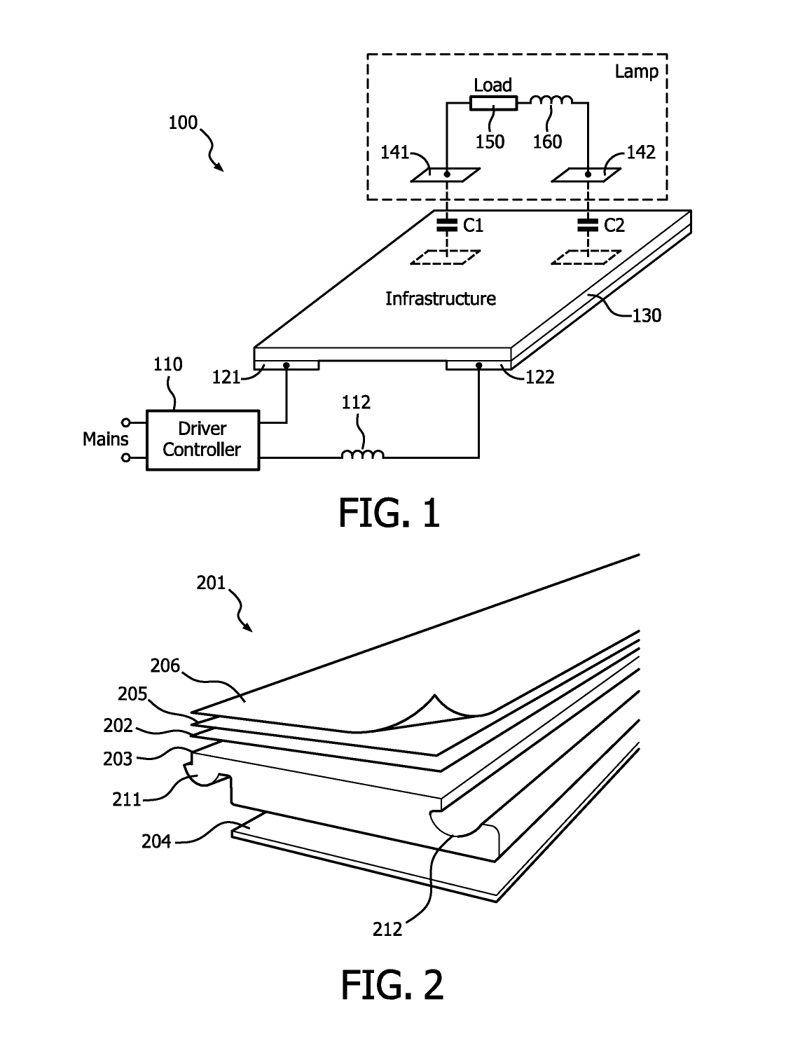

FIG. 1 is a typical arrangement of a capacitive power system for wireless power transfers over a flat structure.

FIG. 2 is a diagram of capacitive power enabled laminate flooring according to an embodiment of the invention.

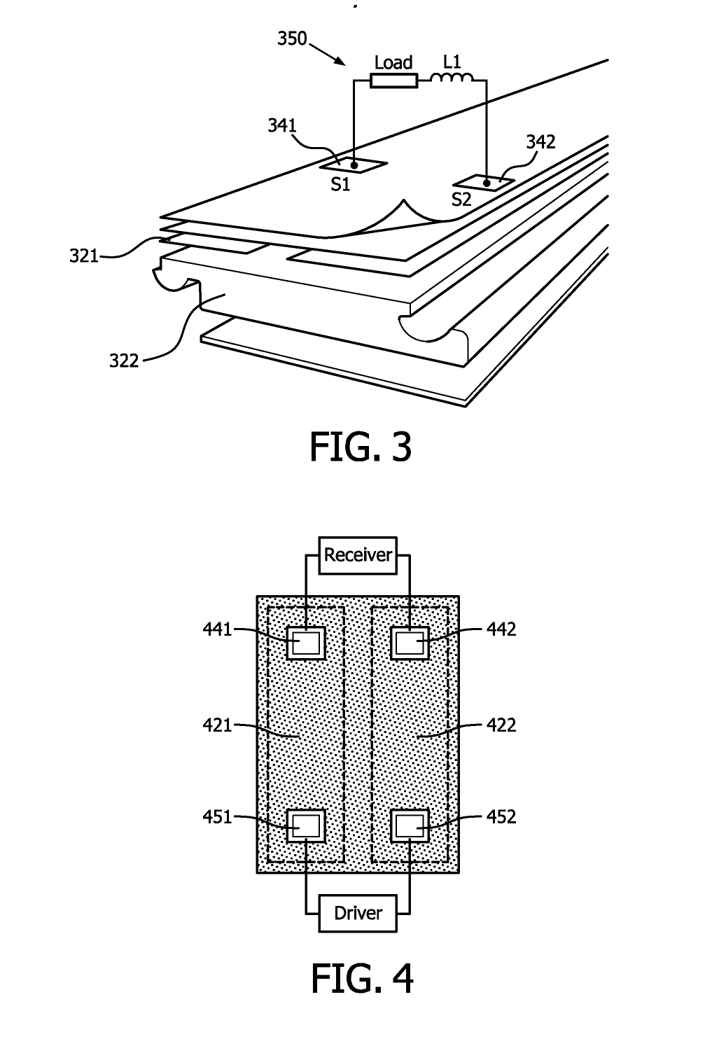

FIG. 3 is a diagram of capacitive power enabled laminate flooring according to another embodiment of the invention.

FIG. 4 shows how driver power is supplied using a capacitive connection according to an embodiment of the invention.

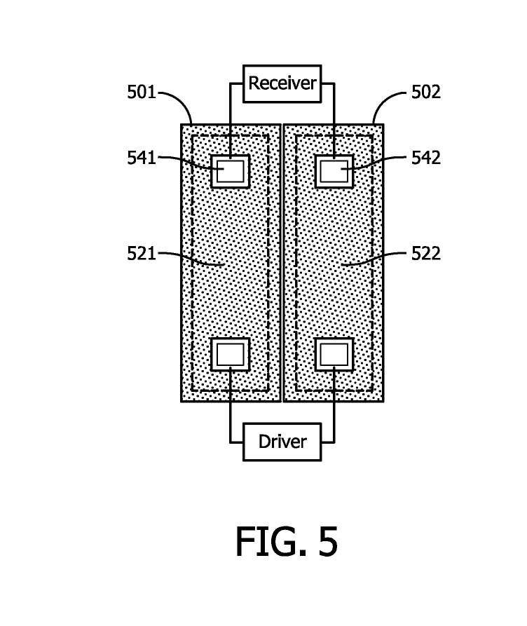

FIG. 5 shows a scheme of capacitive power transfer using two different laminate flooring panels according to an embodiment of the invention.

It is important to note that the embodiments disclosed are only examples of the many advantageous uses of the innovative teachings herein. In general, statements made in the specification of the present application do not necessarily limit any of the various claimed inventions. Moreover, some statements may apply to some inventive features but not to others. In general, unless otherwise indicated, singular elements may be in plural and vice versa with no loss of generality. In the drawings, like numerals refer to like parts through several views.

A capacitive power transfer system can also be utilized to transfer power over large areas that have a flat structure, such as windows, walls, floors, etc. An example of such a capacitive power transfer system is system 100, depicted in FIG. 1. As illustrated in FIG. 1, a typical arrangement of such a system includes a pair of receiver electrodes 141, 142 connected to a load 150 and an inductor 160. The system 100 also includes a pair of transmitter electrodes 121, 122 connected to a power driver 110 and an insulating layer 130.

The transmitter electrodes 121, 122 are arranged on one side of the insulating layer 130 and the receiver electrodes 141, 142 are arranged on the other side of the insulating layer 130. A power is supplied to the load 150 by placing the receiver electrodes 141, 142 in proximity to the transmitter electrodes 121 and 122 on either side of the insulating layer 130, without having a direct contact between the two. This arrangement forms capacitive impedance between the pair of transmitter electrodes 121, 122 and the receiver electrodes 141, 142. Therefore, a power signal generated by the power driver is wirelessly transferred from the transmitter electrodes 121, 122 to the receiver electrodes 141, 142 to power the load 150. Thus, no mechanical connector or any electrical contact is required in order to power the load 150.

In an embodiment, the connection between the transmitter electrodes 121, 122 to the driver 110 is by means of a galvanic contact. In another embodiment, a capacitive in-coupling can be applied between the driver 110 and the electrodes 121,122, whereby no wire connections are needed. This embodiment is advantageous in a modular infrastructure for easy extension of the infrastructure.

The system shown in FIG. 1 includes two optional inductors 112, 160 that match a frequency of the power signal to a series-resonant frequency of the system, thereby improving the efficiency of the power transfer.

The driver 110 outputs an AC voltage signal with a series-resonant frequency of a circuit consisting of the capacitors and inductors 112, 160. The capacitors (C1 and C2) are the capacitive impedance of the transmitter electrodes 121, 122 and receiver electrodes 141, 142 (shown in dotted lines in FIG. 1). The capacitive impedances and inductor 160 cancel each other at the resonance frequency, resulting in a low-ohmic circuit. The driver controller 110 generates an AC signal of which amplitude, frequency, and waveform can be controlled. The output signal typically has amplitude of tens of volts and a frequency of up to a few Mega Hertz (MHz). In an exemplary embodiment, the output signal is typically 50V/400 kHz. Thus, the system 100 is capable of delivering power to the load 150 with very low power losses.

The load may be, for example, a LED, a LED string, a lamp, displays, computers, power chargers, loudspeakers, and the like. For example, the system 100 can be utilized to power lighting fixtures installed on a wall.

The transmitter electrodes 121, 122 are comprised of two separate bodies of conductive material placed on one side of the insulating layer 130 that is not adjacent to the receiver electrodes 141, 142. For example, as illustrated in FIG. 1, the transmitter electrodes 121, 122 are at the bottom of the insulating layer 130. In another embodiment, the transmitter electrodes 121, 122 can be placed on opposite sides of the insulating layer 130. The transmitter electrodes 121, 122 can be any shape including, for example, a rectangle, a circle, a square, or combinations thereof. The conductive material of each of the transmitter electrode may be, for example, carbon, aluminum, indium tin oxide (ITO), organic material, such as PEDOT, copper, silver, conducting paint, or any conductive material.

The receiver electrodes 141, 142 can be of the same conductive material as the transmitter electrodes 121, 122 or made of different conductive material. The total capacitance of the system 100 is formed by the overlap areas of respective transmitter and receiver electrodes 121, 141, and 122, 142, as well as the thickness and material properties of the insulating layer 130. The capacitance of the system 100 is illustrated as C1 and C2 in FIG. 1. In order to allow electrical resonance, the system 100 should also include an inductive element. This element may be in a form of one or more inductors that are part of the transmitter electrodes or the receiver electrodes, distributed over the driver 110 and the load (e.g., inductors 160 and 112 shown in FIG. 1), inductors incorporated within insulating layer 130, or any combination thereof. In an embodiment, an inductor utilized in the system 100 can be in a form of a lumped coil.

The load 150 allows for an AC bi-directional current flow. In an embodiment, the load 150 may include a diode or an AC/DC converter to locally generate a DC voltage. The load 150 may further include electronics for controlling or programming various functions of the load 150 based on a control signal generated by the driver 110.

Another embodiment for dimming and/or color setting of a lamp acting as a load 150 includes misplacing the transmitter and receiver electrodes, i.e., when the respective electrodes 121/141 and 122/144 do not fully overlap each other. In such a case, the electrical circuit is out of resonance, whereby less power is transferred from the driver 110 to the lamp (load 150). The state in which the circuit does not resonate is also referred to as detuning.

In capacitive powering systems that include multiple loads, the power consumed by the different loads may be different from each other. The power of the AC signal is determined by the load that consumes the highest power. When a “high power load” and a “low power load” are connected in the system, the power AC signal can damage the latter load. To overcome this problem an overload protection is required.

There exists a desire to provide electrical power wirelessly from the floor. One approach is to put the power transferring electrodes under the flooring. One popular kind of flooring is laminate flooring. Laminate flooring is a multi-layer synthetic flooring product fused together in a lamination process. Laminate flooring simulates wood (or stone, in some cases) with a photographic layer under a clear protective layer. The inner core layer is usually comprised of melamine resin and fiber board materials. There may be a glue backing for ease of installation. It has the advantage of durability in contrast with carpet, and the advantage of attractiveness at a lower cost in contrast with natural flooring materials.

The above laminate flooring contains an electrode that constitutes one part of a capacitor formed in a wireless power system. The power receiving device contains an electrode that constitutes the counter plate of the capacitor. Another laminate floor element forms the second part of a capacitor.

Laminate flooring with an integrated conductive layer may exist as anti-static laminate flooring panels. For example, KRONO ORIGINAL (Trademark) sells anti-static laminate flooring panels that incorporate “an innovative layer directly below the decor and provides complete protection against unpleasant shocks.” However, these panels are not suitable for power transfer, because the conductivity of the layer may not be continuous or may not be sufficient for efficient power transfer.

A problem exists with laminate flooring because the thickness of the laminate flooring is too thick to enable efficient capacitive power transfer. The thickness causes the capacitive coupling to be very small, preventing an efficient high power transfer.

The present invention proposes a solution to the above problem by placing a conductive layer between a non-conductive top layer and an inner core layer of a flooring panel. This conductive layer is used to transfer power in a capacitive way. The advantage of this approach is that the protective top layer is thin, which enables efficient high power transfer. Furthermore, the non-conductive top layer also protects the user from any electrical voltage that is applied to the conductive layer. Thus, the electrodes in the power transferring device and the corresponding electrodes in the power receiving device are brought together in close proximity for efficient high power transfer. For aesthetic reasons, a photographic layer is included to hide the electrodes and to provide a more realistic wooden surface.

One embodiment disclosed herein includes a laminate panel for wireless capacitive power transfers, including: a conductive layer; a non-conductive top layer above the conductive layer; and an inner core layer under the conductive layer.

Another embodiment disclosed herein includes a system for transferring power wirelessly to a power receiving device, including: a plurality of laminate panels, wherein each of the plurality of laminate panels includes: a conductive layer; a non-conductive top layer above the conductive layer; and an inner core layer under the conductive layer; wherein the conductive layers of a first and second of the plurality of laminate panels are electrically coupled to a power driver; wherein a first and second receiver electrodes of the power receiving device are placed on the first and second panels, respectively, to form a first and second capacitors; wherein a power signal generated by the power driver is wirelessly transferred from the conductive layers of the first and second panels to the first and second receiver electrodes to power a load in the power receiving device.

The load may be in series with an inductor in the power receiving device, wherein a frequency of the power signal substantially matches a series-resonance frequency of the inductor in the power receiving device and a capacitive impedance between the first and second capacitors.

Another embodiment disclosed herein includes a system for transferring power wirelessly to a power receiving device, comprising: a laminate panel, wherein the laminate panel comprises: a conductive layer; a non-conductive top layer above the conductive layer; and an inner core layer under the conductive layer, wherein the conductive layer is patterned to form at least a first and second transmitter electrodes that are electrically coupled to a power driver, a first and second of receiver electrodes of the power receiving device are placed on the laminate panel over the first and second transmitter electrodes respectively to form a first and second capacitors, a power signal generated by the power driver is wirelessly transferred from the first and second transmitter electrodes to the first and second of receiver electrodes to power a load in the power receiving device.

An embodiment according to the present invention is shown in FIG. 2. A laminate flooring panel 201 includes a layer of conductive material 202, an inner core layer 203, a photographic layer 205, and a protective layer 206. The conductive layer 202 is between the inner core layer 203 and the protective layer 206. The protective layer 206 is non-conductive and may serve as a dielectric medium in the capacitive power transfer system. Although optional, the photographic layer 205 simulates a wood pattern, a stone pattern, or other colors and patterns, and is usually included for aesthetic reasons. Alternatively, a single layer may serve as both the photographic layer and the protective layer. The laminate flooring panel has an optional backing layer 204 (e.g., a sound absorbing layer). Capacitive power is provided through this laminate flooring panel, using a patterned conductive layer, or using a plurality of laminate flooring panels. As shown in FIG. 2, the core layer 203 includes a tongue 211 and groove 212 as components of an engagement mechanism, so that a number of such laminate flooring panels can be attached, or “clicked”, to one another. According to one embodiment, when two panels are connected to one another, their conductive layers are also electrically connected to one another. This gives the capacitive power transfer system a larger electrode footprint and thus gives a user more flexibility to choose the best and most convenient location to transfer power to devices.

FIG. 3 shows an embodiment where the conductive layer is patterned in such a way that it may be used for capacitive power transfer. For example, the conductive layer includes two strips of conductive material 321, 322 acting as two transmitter electrodes. A load 350 is placed in such a way that receiver electrodes 341, 342 are arranged over the conductive strips 321, 322. The receiver electrodes 341, 342 pair with conductive strips 321, 322, respectively, to form two capacitor impedances. The load 350 is in series with an inductor L1 in a power receiving device. For more efficient power transfer, the frequency of the power signal substantially matches a series-resonance frequency of the inductor and the capacitive impedance between the capacitors formed.

This embodiment also provides a method for capacitive power transfer by using a laminate flooring panel with a patterned integrated conductive layer.

The strips of conductive material are connected to an AC power driver with a conductive connection, such as a connector or soldering joint, etc. However, in one embodiment, the strips of conductive materials are connected to a second capacitive power connection. As shown in FIG. 4, near one end of the laminate flooring panel, capacitive couplings are located between the conductive strips 421, 422 with the corresponding electrodes 441, 442 for supplying power to the load. On the other end of the panel, there are capacitive couplings between the conductive strips 421 and 422 with the corresponding electrodes 451 and 452 for receiving power from the driver. In this way there is more freedom to place the load and driver.

In another embodiment, the conductive layer is not patterned, but capacitive power transfer is done by placing the electrodes 541 and 542 on two different laminate flooring panels 501 and 502, as shown in FIG. 5. This embodiment provides a method for capacitive power transfer using two laminate flooring panels with an integrated conductive layer. In this case, laminate panel 501 comprises a conductive layer 521 that acts as the first transmitter electrode, and laminate panel 502 comprises a conductive layer 522 that acts as the second transmitter electrode.

The conductivity of the conductive layer in an embodiment of the present invention is substantially greater than a typical conductivity of a layer of anti-static laminate. An anti-static tile or laminate is considered electrostatic discharge (ESD) safe when the resistance to ground is greater than 25,000 Ohms (Ω) and less than 35 MΩ. The ESD-safe specification prevents the risk of people getting electrocuted. In one embodiment of the invention, when the electrodes are coupled to the power driver via conductive wires or connectors, the resistance of the electrode to driver is far less than 25,000 Ω, preferably less than 1 kΩ, and more preferably less than 100 Ω. In another embodiment of the invention, when the electrodes are coupled to the power driver in a capacitive way, such as the arrangement shown in FIG. 4, the DC resistance of the electrode to driver is much greater than 1 kΩ, but the AC resistance, which is the sum of all AC losses between the electrodes and driver, is less than 1 kΩ. In a preferred embodiment, both the AC and DC resistances between the electrodes and the driver are less than 1 kΩ, enabling the laminate panel to provide flexibility for coupling the electrodes with the power driver via conductive wires or in a capacitive way. The driver itself is isolated to the ground to prevent the risk of electrocution.

Although various embodiments described herein relate to laminate flooring, the invention is also applicable to other laminate surfaces, such as laminate wall panels, counter tops, furniture surfaces, etc.

The present invention has been described at some length and with some particularity with respect to the several described embodiments. However, it is not intended that it should be limited to any such particulars, or embodiments, or any particular embodiment. Instead, it is to be construed with references to the appended claims so as to provide the broadest possible interpretation of such claims in view of the prior art, and therefore, to effectively encompass the intended scope of the invention. Furthermore, the foregoing describes the invention in terms of embodiments foreseen by the inventor for which an enabling description was available, notwithstanding that insubstantial and presently unforeseeable modifications of the invention may nonetheless represent equivalents thereto.

1. A laminate panel for wireless capacitive power transfers, comprising:
a conductive layer;
a non-conductive top layer above the conductive layer (202);
an inner core layer under the conductive layer (202); and
an engagement mechanism for engaging another same laminate panel such that when the two said laminate panels are engaged by the engagement mechanism, the conductive layers of the two engaged panels are electrically connected to each other.

2. The laminate panel of claim 1, wherein the conductive layer is patterned to form at least a pair of transmitter electrodes.

3. (canceled)

4. The laminate panel of claim 1, further comprising a photographic layer between the non-conductive top layer and the conductive layer.

5. A system for transferring power wirelessly to a power receiving device, comprising:
a plurality of laminate panels;
wherein each of the plurality of laminate panels comprises:
a conductive layer;
a non-conductive top layer above the conductive layer;
an inner core layer (203) under the conductive layer; and
an engagement mechanism for engaging another same laminate panel such that when the two said laminate panels are engaged by the engagement mechanism, the conductive layers of the two engaged panels are electrically connected to each other;
wherein the conductive layers of a first and second of the plurality of laminate panels (501, 502) are electrically coupled to a power driver;
wherein a first and second receiver electrodes of the power receiving device are placed on the first and second panels respectively to form a first and second capacitive impedances;
wherein a power signal generated by the power driver is wirelessly transferred from the conductive layers of the first and second panels to the first and second of receiver electrodes to power a load in the power receiving device.

6. The system of claim 5, wherein the load is in series with an inductor in the power receiving device, wherein a frequency of the power signal substantially matches a series-resonance frequency of the inductor in the power receiving device and the first and second capacitive impedances.

7. The system of claim 5, wherein the conductive layers of the first and second panels couple with the power driver by connecting to two respective terminals of the power driver with conductive wires or connectors.

8. The system of claim 7, wherein resistance of the conductive layers to the power driver is less than 1 kΩ.

9. The system of claim 5, wherein the conductive layers of the first and second panels capacitively couple with the power driver by placing a first and second driver electrodes of the power driver over the conductive layers of the first and second panels respectively.

10. The system of claim 9, wherein resistance of the conductive layers to the power driver is less than 1 kΩ.

11. A system for transferring power wirelessly to a power receiving device, comprising:
a laminate panel;
wherein the laminate panel comprises:
a conductive layer;
a non-conductive top layer above the conductive layer;
an inner core layer under the conductive layer; and
an engagement mechanism for engaging another same laminate panel;
wherein the conductive layer is patterned to form at least a first and second transmitter electrodes that are electrically coupled to a power driver;
wherein when the two said laminate panels are engaged by the engagement mechanism, the respective transmitter electrodes of the two engaged panels are electrically connected to each other;
wherein a first and second receiver electrodes of the power receiving device are placed on the laminate panel over the first and second transmitter electrodes respectively to form a first and second capacitive impedances;
wherein a power signal generated by the power driver is wirelessly transferred from the first and second transmitter electrodes to the first and second of receiver electrodes to power a load in the power receiving device.

12. The system of claim 11, wherein the load is in series with an inductor in the power receiving device, wherein a frequency of the power signal substantially matches a series-resonance frequency of the inductor in the power receiving device and the first and second capacitive impedances.

13. The system of claim 11, wherein the first and second transmitter electrodes couple with the power driver by connecting to two respective terminals of the power driver with conductive wires or connectors.

14. The system of claim 13, wherein resistance of the transmitter electrodes to the power driver is less than 1 kΩ.

15. The system of claim 11, wherein the first and second transmitter electrodes capacitively couple with the power driver by placing a first and second driver electrodes of the power driver over the first and second transmitter electrodes respectively.

16. The system of claim 15, wherein resistance of the transmitter electrodes to the power driver is less than 1 kΩ.
